(19) United States
(12) Patent Application Publication
(10) Pub. No.: US 2026/0047287 A1
(43) Pub. Date: Feb. 12, 2026

(54) DISPLAY APPARATUS AND ELECTRONIC DEVICE HAVING THE SAME

(71) Applicant: Samsung Display Co., Ltd., Yongin-si (KR)

(72) Inventors: Haeyeon Lee, Yongin-si (KR); Jungwoo Lee, Yongin-si (KR); Daewoong Ham, Yongin-si (KR); Minhee Choi, Yongin-si (KR); Wonse Lee, Yongin-si (KR)

(21) Appl. No.: 19/240,989

(22) Filed: Jun. 17, 2025

(30) Foreign Application Priority Data
Aug. 9, 2024 (KR) 10-2024-0107091

(51) Int. Cl. H10K 59/131; G09G 3/00; H10K 77/10

(52) U.S. Cl. CPC H10K 59/131; G09G 3/006; H10K 77/111; G09G 2330/12

(57) ABSTRACT

A display apparatus includes a substrate including a first area, a second area, and a bending area between the first area and the second area; a plurality of test transistors on the second area; a first line extending in a first direction; a second line connected to the first line through a first connection line and a second connection line; and a test pad connected to the second line, wherein the first line includes a first-1 portion connected to the first connection line, a first-2 portion connected to the second connection line, and a first-3 portion between the first-1 portion and the first-2 portion, and wherein the plurality of test transistors are connected to the first-3 portion.

### CROSS-REFERENCE TO RELATED APPLICATION

The present application claims priority to and the benefit of Korean Patent Application No. 10-2024-0107091, filed on Aug. 9, 2024, in the Korean Intellectual Property Office, the entire disclosure of which is incorporated herein by reference.

### BACKGROUND

### 1. Field

Aspects of embodiments of the present disclosure relate to a display apparatus including a lighting inspection unit.

### 2. Description of the Related Art

A display apparatus has a display area in which a plurality of pixels are arranged, each of the pixels including a display element. Also, lines for transmitting various electrical signals to the pixels may be arranged in a display area or a non-display area outside the display area. For example, display elements are electrically connected to a plurality of data lines, and the plurality of data lines are electrically connected to a lighting inspection unit on the non-display area. The lighting inspection unit may be electrically connected to a test pad, and electrical signals from the test pad may be transmitted to the plurality of pixels through the data lines. Accordingly, the display elements included in the plurality of pixels emit light so that the plurality of pixels may be inspected for the existence or absence of defects.

The above information disclosed in this Background section is only for enhancement of understanding of the background of the invention and therefore it may contain information that does not form the prior art.

### SUMMARY

However, in related-art display apparatuses, when the test pad is connected only to one of opposite ends of a line to which a plurality of test transistors included in the lighting inspection unit is connected, different electrical signals may be transmitted to the display elements, resulting in inaccurate results during lighting inspection.

Aspects of some embodiments of the present disclosure are directed to a display apparatus that may be accurately inspected for defects during a manufacturing process. However, this is just an example, and the scope of the disclosure is not limited thereby.

Additional aspects will be set forth in part in the description which follows and, in part, will be apparent from the description, or may be learned by practice of the presented embodiments of the disclosure. According to some embodiments of the disclosure, there is provided a display apparatus including: a substrate including a first area, a second area, and a bending area between the first area and the second area; a plurality of test transistors on the second area; a first line extending in a first direction; a second line connected to the first line through a first connection line and a second connection line; and a test pad connected to the second line, wherein the first line includes a first-1 portion connected to the first connection line, a first-2 portion connected to the second connection line, and a first-3 portion between the first-1 portion and the first-2 portion, and wherein the plurality of test transistors are connected to the first-3 portion.

In some embodiments, the second line may be spaced apart from the first line in a second direction crossing the first direction, and each of the first connection line and the second connection line may extend in the second direction.

In some embodiments, the second line may extend in the first direction.

In some embodiments, the second line may include a second-1 portion connected to the first connection line, a second-2 portion connected to the second connection line, and a second-3 portion between the second-1 portion and the second-2 portion, and the test pad may be connected to the second-3 portion.

In some embodiments, the first area may be symmetrical with respect to a symmetry line extending in the second direction, and the second area may be asymmetrical with respect to the symmetry line.

In some embodiments, the second area may include a second-1 area and a second-2 area; in a plan view, the second-1 area may be positioned on one side of the symmetry line; in a plan view, the second-2 area may be positioned on another side of the symmetry line; a size of the second-2 area may be greater than a size of the second-1 area; and the test pad may be on the second-2 area.

In some embodiments, the first area may include a display area and a plurality of display elements on the display area, and each of the plurality of test transistors may be electrically connected to a corresponding one of a plurality of data lines electrically connected to the plurality of display elements.

According to some embodiments of the disclosure, there is provided a display apparatus including: a substrate including a first area, a second area, and a bending area between the first area and the second area; a plurality of first test transistors, a plurality of second test transistors, and a plurality of third test transistors on the second area; a first line extending in a first direction; a second line connected to the first line through a first connection line and a second connection line; and a first test pad connected to the second line, wherein the first line includes a first-1 portion connected to the first connection line, a first-2 portion connected to the second connection line, and a first-3 portion between the first-1 portion and the first-2 portion, and wherein the plurality of first test transistors are connected to the first-3 portion.

In some embodiments, the second line may be spaced apart from the first line in a second direction crossing the first direction, and each of the first connection line and the second connection line may extend in the second direction.

In some embodiments, the second line may extend in the first direction.

In some embodiments, the second line may include a second-1 portion connected to the first connection line, a second-2 portion connected to the second connection line, and a second-3 portion between the second-1 portion and the second-2 portion, and the first test pad may be connected to the second-3 portion.

In some embodiments, the display apparatus may further include a third line extending in the first direction; a fourth line connected to the third line through a third connection line and a fourth connection line; and a second test pad connected to the fourth line. The third line may include a third-1 portion connected to the third connection line, a third-2 portion connected to the fourth connection line, and a third-3 portion between the third-1 portion and the third-2 portion, and the plurality of second test transistors may be connected to the third-3 portion.

In some embodiments, the fourth line may be spaced apart from the third line in a second direction crossing the first direction, the fourth line may extend in the first direction, and each of the third connection line and the fourth connection line may extend in the second direction.

In some embodiments, the fourth line includes a fourth-1 portion may be connected to the third connection line, a fourth-2 portion connected to the fourth connection line, and a first-3 portion between the fourth-1 portion and the fourth-2 portion, and the second test pad may be connected to the fourth-3 portion.

In some embodiments, the display apparatus may further include a fifth line extending in the first direction; a sixth line connected to the fifth line through a fifth connection line and a sixth connection line; and a third test pad connected to the sixth line. The fifth line may include a fifth-1 portion connected to the fifth connection line, a fifth-2 portion connected to the sixth connection line, and a fifth-3 portion between the fifth-1 portion and the fifth-2 portion, and the plurality of third test transistors may be connected to the fifth-3 portion.

In some embodiments, the sixth line may be spaced apart from the fifth line in a second direction crossing the first direction, the sixth line may extend in the first direction, and each of the fifth connection line and the sixth connection line may extend in the second direction.

In some embodiments, the sixth line may include a sixth-1 portion connected to the fifth connection line, a sixth-2 portion connected to the sixth connection line, and a sixth-3 portion between the sixth-1 portion and the sixth-2 portion, and the third test pad may be connected to the sixth-3 portion.

In some embodiments, the first area may be symmetrical with respect to a symmetry line extending in a second direction crossing the first direction, and the second area may be asymmetrical with respect to the symmetry line.

In some embodiments, the second area may include a second-1 area and a second-2 area; in a plan view, the second-1 area may be positioned on one side of the symmetry line; in a plan view, the second-2 area may be positioned on another side of the symmetry line; a size of the second-2 area may be greater than a size of the second-1 area; and the first test pad may be on the second-2 area.

In some embodiments, the first area may include a display area and a plurality of display elements on the display area; each of the plurality of first test transistors may be electrically connected to a corresponding one of a plurality of first data lines, the plurality of first data lines being electrically connected to display elements capable of emitting first-color light from among the plurality of display elements; each of the plurality of second test transistors may be electrically connected to a corresponding one of a plurality of second data lines, the plurality of second data lines being electrically connected to display elements capable of emitting second-color light from among the plurality of display elements; and each of the plurality of third test transistors may be electrically connected to a corresponding one of a plurality of third data lines, the plurality of third data lines being electrically connected to display elements capable of emitting third-color light from among the plurality of display elements.

According to some embodiments of the disclosure, there is provided an electronic device including: an input module configured to receive input data from a user; a memory configured to store the input data; a processor configured to perform computations based on the input data and provide output data; and a display apparatus configured to display an image to the user based, in part, on the input data and the output data, the display apparatus including: a substrate including a first area, a second area, and a bending area between the first area and the second area; a plurality of test transistors on the second area; a first line extending in a first direction; a second line connected to the first line through a first connection line and a second connection line; and a test pad connected to the second line, wherein the first line includes a first-1 portion connected to the first connection line, a first-2 portion connected to the second connection line, and a first-3 portion between the first-1 portion and the first-2 portion, and wherein the plurality of test transistors are connected to the first-3 portion.

In some embodiments, the electronic device may be a smartphone.

Other aspects, features and advantages other than those described above will become apparent from the following detailed description, claims and drawings for working the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a display apparatus in an unbent configuration according to some embodiments of the present disclosure;

FIG. 2 is a side view schematically illustrating the display apparatus of FIG. 1 in a bent configuration according to some embodiments of the present disclosure;

FIG. 3 is a plan view schematically illustrating a display apparatus according to some embodiments of the present disclosure;

FIG. 4 is an equivalent circuit diagram of a pixel circuit included in a display apparatus according to some embodiments of the present disclosure;

FIG. 5 is a cross-sectional view taken along the line I-I′ and schematically illustrating a cross section of the display apparatus of FIG. 3 according to some embodiments of the present disclosure;

FIG. 6 is an enlarged view schematically illustrating region A of the display apparatus of FIG. 3 according to some embodiments of the present disclosure;

FIG. 7 is a cross-sectional view taken along the line II-II′ and schematically illustrating a cross section of the display apparatus of FIG. 6 according to some embodiments of the present disclosure;

FIG. 8 is a cross-sectional view taken along the line III-III′ and schematically illustrating a cross section of the display apparatus of FIG. 6 according to some embodiments of the present disclosure;

FIG. 9 is a plan view schematically illustrating a portion of a display apparatus according to a Comparative Example;

FIG. 10 is a plan view schematically illustrating a portion of a display apparatus according to some other embodiments of the present disclosure;

FIG. 11 is a cross-sectional view, taken along the line IV-IV′ and schematically illustrating a cross section of the display apparatus of FIG. 10 according to some embodiments of the present disclosure;

FIG. 12 is a cross-sectional view taken along the line V-V′ and schematically illustrating a cross section of the display apparatus of FIG. 10 according to some embodiments of the present disclosure;

FIG. 13 is a cross-sectional view taken along the line VI-VI′ and schematically illustrating a cross section of the display apparatus of FIG. 10 according to some embodiments of the present disclosure; and

FIG. 14 is a cross-sectional view taken along the line VII-VII′ and schematically illustrating a cross section of the display apparatus of FIG. 10 according to some embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “es,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

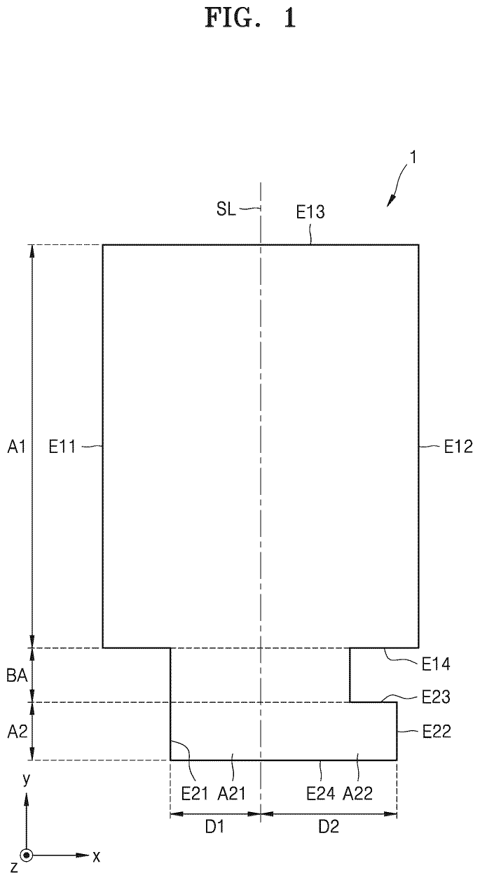

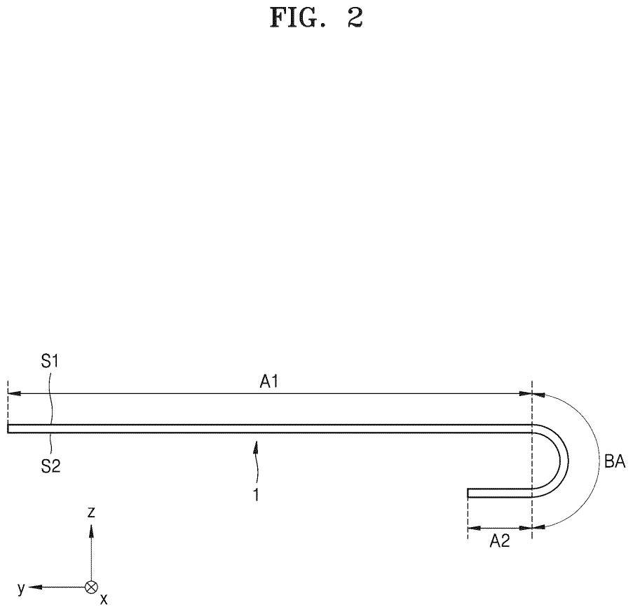

FIG. 1 is a plan view schematically illustrating a display apparatus 1 in an unbent configuration according to some embodiments of the present disclosure. FIG. 2 is a side view schematically illustrating the display apparatus 1 of FIG. 1 in a bent configuration according to some embodiments of the present disclosure.

As shown in FIGS. 1 and 2, the display apparatus 1 may include a first area A1, a second area A2, and a bending area BA between the first area A1 and the second A2. For example, the display apparatus 1 may include the first area A1, the bending area BA outside the first area A1, and the second area A2 on the opposite side of the first area A1 with respect to the bending area BA.

The first area A1 may include a display area and a non-display area, and the second area A2 may include only a non-display area. The display apparatus 1 may be bent in the bending area BA, as shown in FIG. 2, so that, in a plan view (e.g., when viewed from above or from a z-axis direction), at least a portion of the second area A2 overlaps with the first area A1. For example, the display apparatus 1 may be bent with respect to a bending axis extending from the bending area BA in a first direction (e.g., an x-axis direction). When the display apparatus 1 is bent in the bending area BA, a portion of the non-display area may not be visible when the display apparatus 1 is viewed in a-z direction. Accordingly, a visible area of the non-display area may be reduced. The remaining areas other than the bending area BA, i.e., the first area A1 and the second area A2, may have an approximately flat surface. For example, a width in the first direction (e.g., x-axis direction) in the bending area BA may be less than a width in the first direction (e.g., x-axis direction) in the first area A1. Accordingly, the display apparatus 1 may be easily bent in the bending area BA.

The display apparatus 1 may include a first surface S1 and a second surface S2 opposite to the first surface S1. The display apparatus 1 may display an image on the first surface S1. For example, the first surface S1 of the display apparatus 1 may include a display surface. For example, the first surface S1 of the first area A1 of the display apparatus 1 may include a display surface. In a case where the display apparatus 1 is bent in the bending area BA, the second surface S2 of the first area A1 and the second surface S2 of the second area A2 may be arranged to face each other.

As shown in FIG. 1, edges of the first area A1 may have an overall shape similar to a rectangle or a square. For example, the first area A1 may include a first-1 edge E11 and a first-2 edge E12 facing each other, and a first-3 edge E13 and a first-4 edge E14 facing each other and positioned between the first-1 edge E11 and the first-2 edge E12. The first-1 edge E11 and the first-2 edge E12 may be spaced apart from each other in the first direction (e.g., the x-axis direction), and the first-3 edge E13 and the first-4 edge E14 may be spaced apart from each other in a second direction (e.g., a y-axis direction), the second direction (e.g., the y-axis direction) crossing the first direction (e.g., the x-axis direction). The first-1 edge E11 and the first-2 edge E12 may extend in the second direction (e.g., the y-axis direction), and the first-3 edge E13 and the first-4 edge E14 may extend in the first direction (e.g., the x-axis direction).

This first area A1 may be provided in a symmetrical shape centered on a symmetry line SL extending in the second direction (e.g., the y-axis direction). For example, the first area A1 may be symmetrical with respect to the symmetry line SL. For example, a distance between the first-1 edge E11 and the symmetry line SL may be equal or similar to a distance between the first-2 edge E12 and the symmetry line SL. For example, the first-1 edge E11 and the first-2 edge E12 may be spaced apart from each other in the first direction (e.g., the x-axis direction), and in the disclosure, the symmetry line SL may refer to an imaginary line connecting points that are at the same vertical distance from each of the first-1 edge E11 and the first-2 edge E12. This symmetry line SL may extend in the second direction (e.g., the y-axis direction). For example, the first area A1 may be adjacent to a second-3 edge E23 from among a second-1 edge E21 to a second-4 edge E24 of the second area A2.

Similarly, edges of the second area A2 may also have an overall shape similar to a rectangle or a square. For example, the second area A2 may include the second-1 edge E21 and a second-2 edge E22 facing each other, and the second-3 edge E23 and the second-4 edge E24 facing each other and positioned between the second-1 edge E21 and the second-2 edge E22. The second-1 edge E21 and the second-2 edge E22 may extend in the second direction (e.g., the y-axis direction), and the second-3 edge E23 and the second-4 edge E24 may extend in the first direction (e.g., the x-axis direction).

This second area A2 may be provided in an asymmetrical shape with respect to the symmetry line SL extending in the second direction (y-axis direction). The display apparatus 1 may be included in an electronic device and may be disposed inside a housing of an electronic apparatus having an accommodation space. In this case, the second area A2 of the display apparatus 1 may be provided in an asymmetrical shape considering a position relationship between elements included in the electronic device other than the display apparatus 1 and the display apparatus 1. For example, the second area A2 may be asymmetrical with respect to the symmetry line SL. For example, a first distance D1 between the second-1 edge E21 and the symmetry line SL may be different from a second distance D2 between the second-2 edge E22 and the symmetry line SL. For example, the second distance D2 may be greater than the first distance D1.

Accordingly, a size (or an area) of a portion of the second area A2, the portion being positioned on one side of the symmetry line SL (e.g., in a-x direction of the symmetry line SL), may be different from a size (or an area) of a portion of the second area A2, the portion being positioned on the other side of the symmetry line SL (e.g., a +x direction of the symmetry line SL). For example, the second area A2 may include a second-1 area A21 and a second-2 area A22. In a plan view, the second-1 area A21 may be positioned on one side of the symmetry line SL, and in a plan view, the second-2 area A22 may be positioned on another side of the symmetry line SL. For example, the second-1 area A21 may be adjacent to the second-1 edge E21, and the second-2 area A22 may be adjacent to the second-2 area A22. For example, the second area A2 may be adjacent to the first-4 edge E14 from among the first-1 edge E11 to the first-4 edge E14 of the first area A1.

As shown in FIG. 1, corners of each of the first area A1 and the second area A2 may have sharp portions. However, one or more embodiments are not limited thereto. For example, a corner formed via contact between the first-1 edge E11 and the first-3 edge E13 may have a round shape, and a corner formed via the first-1 edge E11 and the first-4 edge E14 may have a round shape. For example, corners formed via contact between the first-2 edge E12 and the first-3 edge E13 or the first-4 edge E14 may have a round shape.

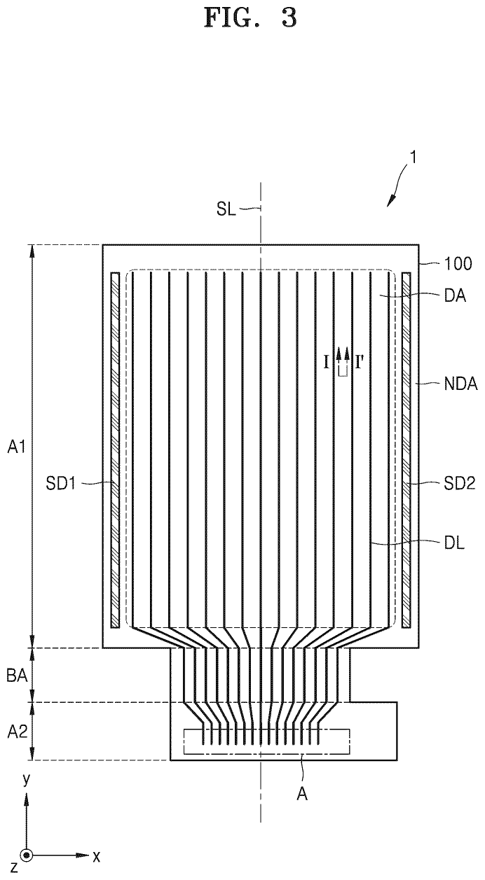

FIG. 3 is a plan view schematically illustrating the display apparatus 1 according to some embodiments of the present disclosure. As shown in FIG. 3, the display apparatus 1 may have a substrate 100.

The substrate 100 may include glass, metal, or polymer resin. The substrate 100 may have flexible or bendable properties. In this case, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, cellulose acetate propionate, or the like. The substrate 100 may have a multi-layer structure including two layers including the polymer resin and a barrier layer including an inorganic material (e.g., silicon oxide (SiOₓ), silicon nitride (SiNₓ), or silicon oxynitride (SiOₓN_{y})) and positioned between the layers, and various modifications may be made. Because the display apparatus 1 has the substrate 100, it can also be considered that the substrate 100 has the first area A1, the second area A2, and the bending area BA described above. Hereinbelow, for convenience, it is assumed that the substrate 100 has the first area A1, the second area A2, and the bending area BA.

The first area A1 may include a display area DA. For example, as shown in FIG. 3, the first area A1 may include the display area DA and a portion of a non-display area NDA outside the display area DA. The second area A2 and the bending area BA may include the non-display area NDA. For example, the display area DA may correspond to a portion of the first area A1, and the non-display area NDA may correspond to the remaining area of the first area A1, the second area A2, and the bending area BA.

A pixel may be disposed on the display area DA. The pixel may include a display element and a pixel circuit electrically connected to the display element. The pixel may be provided in plurality. For example, the display element may be provided in plurality, and the pixel circuits electrically connected to the display elements may also be provided in plurality. For example, a plurality of display elements and a plurality of pixel circuits may be disposed on the display area DA. The display apparatus 1 may provide an image by using light emitted from a plurality of pixels. For example, each of the pixels may emit one of red, green, and blue light. For example, display elements included in the respective pixels may emit one of red, green, and blue light.

The display area DA may have a polygonal shape, including a rectangle, as shown in FIG. 3. For example, the display area DA may have a rectangular shape of which a horizontal length is greater than a vertical length, or a rectangular shape of which a vertical length is greater than a horizontal length, or a square shape. For example, the display area DA may have various shapes, such as an ellipse or a circle. A driver or the like for providing electrical signals or power to the pixels may be disposed on the non-display area NDA. Connection pads to which various electronic elements or printed circuit boards may be electrically connected may be disposed on the non-display area NDA.

For example, a first scan driving unit SD1 and a second scan driving unit SD2 may be disposed on the non-display area NDA. For example, the first scan driving unit SD1 and the second scan driving unit SD2 may be disposed in the first area A1. For example, the first scan driving unit SD1 and the second scan driving unit SD2 may be disposed on the first area A1 to be spaced apart from each other with the display area DA therebetween. The first scan driving unit SD1 may provide scan signals to the pixels through a scan line extending in the first direction (e.g., x-axis direction) into the display area DA. Some of the pixels disposed in the display area DA may be electrically connected to the first scan driving unit SD1, and the remaining ones may be electrically connected to the second scan driving unit SD2. In some embodiments, the second scan driving unit SD2 may be omitted, and the pixels disposed on the display area DA may all be electrically connected to the first scan driving unit SD1.

However, in addition to the above, an emission control driving unit or the like may be disposed on the side of the first scan driving unit SD1 or the second scan driving unit SD2, and may provide an emission control signal or the like to a pixel through an emission control line approximately parallel to the scan line.

Connection pads may be disposed on the non-display area NDA, and a driving chip may be disposed on the non-display area NDA between the display area DA and the connection pads. The connection pads of the display apparatus 1 may be exposed and not covered by an insulating layer, and may be electrically connected to the printed circuit board. For example, the connection pads of the printed circuit board may be electrically connected to the connection pads of the display apparatus 1.

The driving chip may include a data driving unit for generating data signals. The driving chip may provide data signals to the pixels through a data line DL extending in the second direction (y-axis direction) into the display area DA.

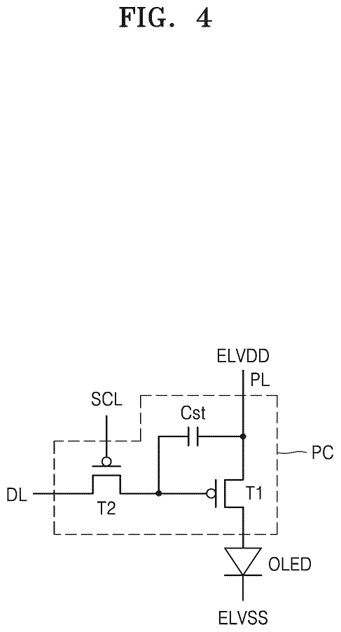

The printed circuit board may transfer signals or power of a control unit to the display apparatus 1. Control signals generated by the control unit may be transmitted to the driving chip, the first scan driving unit SD1, and the second scan driving unit SD2 through the printed circuit board. In addition, the control unit may provide a common voltage ELVSS (see, e.g., FIG. 4) to a common voltage supply line and provide a driving voltage ELVDD (see, e.g., FIG. 4) to a driving power line. The common voltage supply line may have a loop shape with one open side, and partially surround the display area DA in a plan view. The driving power line may extend in the second direction (y-axis direction) into the display area DA.

As described above, because a width of the bending area BA in the first direction (e.g., x-axis direction) is less than a width of the first area A1 in the first direction (e.g., x-axis direction), and the plurality of data lines DL extend from the display area DA to the second area A2, distances between the plurality of data lines DL may vary depending on the area. For example, a distance between the data lines DL in the bending area BA may be less than a distance between the data lines DL on the display area DA. Accordingly, portions of the plurality of data lines DL disposed on a portion of the first area A1 between the display area DA and the bending area BA may be formed with different lengths. For example, the closer the data line DL is to the symmetry line SL, the shorter the length of a portion of the data line DL disposed on a portion of the first area A1 between the data line DL and the bending area BA may be. For example, the closer the data line DL is to the symmetry line SL, the shorter the data line DL may be.

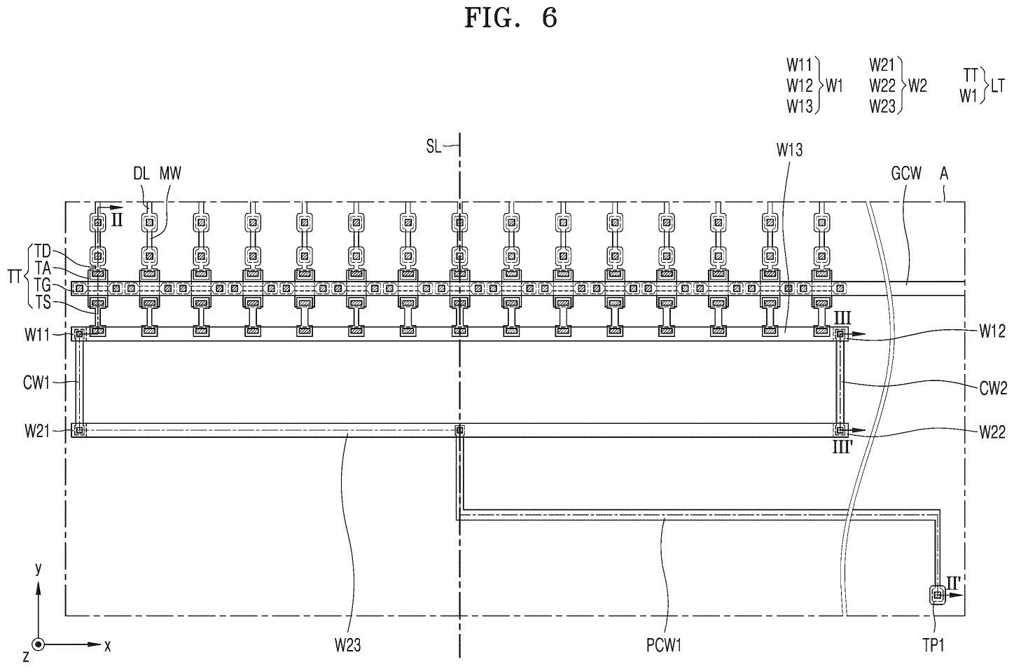

For example, a lighting inspection unit LT (see, e.g., FIG. 6) and a test pad may be disposed on the non-display area NDA under the display area DA. For example, the lighting inspection unit LT may be disposed in the second area A2. The lighting inspection unit LT may be connected to the data line DL electrically connected to a pixel of the display area DA to provide a lighting inspection signal to the data line DL in a lighting inspection process. The lighting inspection unit LT and the test pad are described in detail below.

FIG. 4 is an equivalent circuit diagram of a pixel circuit PC included in the display apparatus 1 according to some embodiments of the present disclosure. As described above, a pixel may include a display element and the pixel circuit PC, and the pixel circuit PC may be electrically connected to the display element. In FIG. 4, an organic light-emitting diode OLED is shown as a display element.

The pixel circuit PC may include a first transistor T1, a second transistor T2, and a storage capacitor Cst. The second transistor T2, which is a switching transistor, may be connected to a scan line SCL and the data line DL, and may be turned on by a switching signal received via the scan line SCL to transmit a data signal received via the data line DL to the first transistor T1. The storage capacitor Cst may have one end electrically connected to the second transistor T2 and the other end electrically connected to a driving voltage line PL, and may store a voltage corresponding to a difference between a voltage received from the second transistor T2 and the driving voltage ELVDD supplied to the driving voltage line PL.

The first transistor T1, which is a driving transistor, may be connected to the driving voltage line PL and the storage capacitor Cst to control a magnitude of a driving current flowing from the driving voltage line PL to the organic light-emitting diode OLED in response to a voltage value stored in the storage capacitor Cst. The organic light-emitting diode OLED may emit light with a certain luminance according to the driving current. An opposite electrode of the organic light-emitting diode OLED may receive the common voltage ELVSS.

In FIG. 4, the pixel circuit PC includes two transistors and one storage capacitor. However, one or more embodiments are not limited thereto. For example, the number of transistors or the number of storage capacitors may variously change depending on the design of the pixel circuit PC.

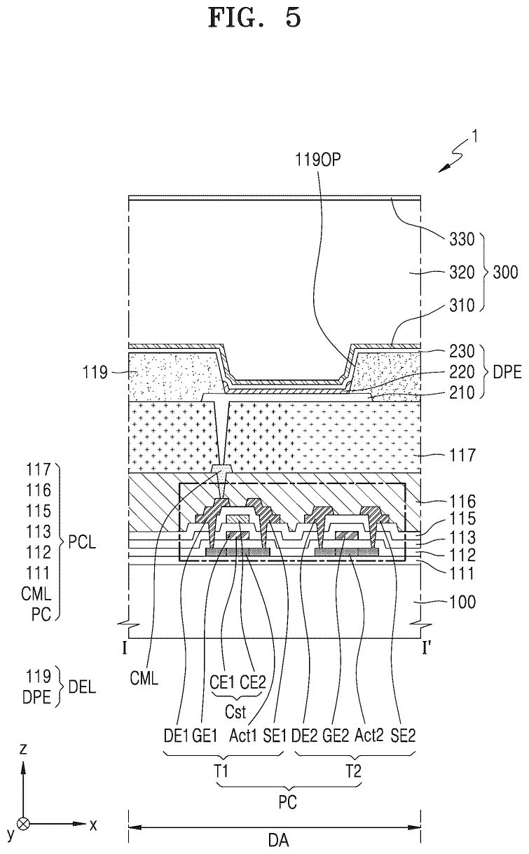

FIG. 5 is a cross-sectional view schematically illustrating a cross section of the display apparatus 1 of FIG. 3, taken along the line I-I′ according to some embodiments of the present disclosure. As shown in FIG. 5, the display apparatus 1 may include the substrate 100, a pixel circuit layer PCL, a display element layer DEL, and an encapsulation layer 300.

The pixel circuit layer PCL may be disposed on the substrate 100. The pixel circuit layer PCL may include the pixel circuit layer PCL, a buffer layer 111, a first gate insulating layer 112, a second gate insulating layer 113, an interlayer insulating layer 115, a first planarization layer 116, a second planarization layer 117, and a connection electrode CML. The pixel circuit PC may include at least one transistor. For example, the pixel circuit PC may include the first transistor T1, the second transistor T2, and the storage capacitor Cst.

The first transistor T1 may include a first semiconductor layer Act1, a first gate electrode GE1, a first source electrode SE1, and a first drain electrode DE1. The pixel circuit layer PCL may further include the buffer layer 111, the first gate insulating layer 112, the second gate insulating layer 113, the interlayer insulating layer 115, the first planarization layer 116, and the second planarization layer 117, which are disposed over or/and under elements of the first transistor T1.

The buffer layer 111 may reduce or block permeation of foreign substances, moisture, or outside air from a lower portion of the substrate 100, and provide a flat surface on the substrate 100. The buffer layer 111 may include an inorganic material, such as oxide or nitride, an organic material, or an organic and inorganic compound, and may have a single-layer or multi-layer structure of an inorganic material and an organic material.

The first semiconductor layer Act1 may be disposed on the buffer layer 111. The first semiconductor layer Act1 may include polysilicon. For example, the first semiconductor layer Act1 may include amorphous silicon, oxide semiconductor, or organic semiconductor. The first semiconductor layer Act1 may include a channel region, a drain region, and a source region, wherein the drain region and the source region are disposed on opposite sides of the channel region, respectively.

The first gate electrode GE1 may overlap with the channel region. The first gate electrode GE1 may include a low-resistance metal material. The first gate electrode GE1 may include a conductive material, including molybdenum (Mo), aluminum (Al), copper (Cu), titanium (Ti), and/or the like, and may have a single-layer or multi-layer structure including the conductive material described above.

The first gate insulating layer 112 may be between the first semiconductor layer Act1 and the first gate electrode GE1. The first gate insulating layer 112 may include an inorganic insulating material, such as SiOₓ, SiNₓ, or SiOₓN_{y}. The second gate insulating layer 113 may cover the first gate electrode GE1. The second gate insulating layer 113 may include an inorganic insulating material, such as SiOₓ, SiNₓ, or SiOₓN_{y}.

A second capacitor electrode CE2 of the storage capacitor Cst may be disposed on the second gate insulating layer 113. The second capacitor electrode CE2 may overlap with the first gate electrode GE1 thereunder. In this case, the first gate electrode GE1 of the first transistor T1 and the second capacitor electrode CE2 overlapping with each other with the second gate insulating layer 113 therebetween may form the storage capacitor Cst. For example, the first gate electrode GE1 of the first transistor T1 may function as a first capacitor electrode CE1 of the storage capacitor Cst, and the storage capacitor Cst and the first transistor T1 may overlap with each other. However, one or more embodiments are not limited thereto, and the storage capacitor Cst may not overlap with the first transistor T1. The second capacitor electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (ca), Mo, Ti), tungsten (W), Cu, and/or the like. The second capacitor electrode CE2 may have a single-layer or multi-layer structure including the materials described above.

The interlayer insulating layer 115 may cover the second capacitor electrode CE2. The interlayer insulating layer 115 may include an inorganic insulating material, such as SiOₓ, SiNₓ, or SiOₓN_{y}.

The first drain electrode DE1 and the first source electrode SE1 may each be disposed on the interlayer insulating layer 115. The first drain electrode DE1 and the first source electrode SE1 may include a material with good conductivity. Each of the first drain electrode DE1 and the first source electrode SE1 may include a conductive material, including Mo, Al, Cu, or Ti, and may have a single-layer or multi-layer structure including the conductive materials described above. For example, at least one of the first drain electrode DE1 and the first source electrode SE1 may have a multi-layer structure of Ti/Al/Ti.

The second transistor T2 may include a second semiconductor layer Act2, a second gate electrode GE2, a second drain electrode DE2, and a second source electrode SE2. The second semiconductor layer Act2, the second gate electrode GE2, the second drain electrode DE2, and the second source electrode SE2 may be similar to the first semiconductor layer Act1, the first gate electrode GE1, the first drain electrode DE1, and the first source electrode SE1, respectively, and thus redundant descriptions thereof are omitted.

The first planarization layer 116 may cover the first drain electrode DE1 and the first source electrode SE1. The first planarization layer 116 may have an approximately flat upper surface. The first planarization layer 116 may include an organic material. For example, the first planarization layer 116 may include general-purpose polymers, such as benzocyclobutene (BCB), polyimide, hexamethyldisiloxane (HMDSO), polymethylmethacrylate (PMMA), and polystyrene (PS), polymer derivatives having a phenol-based group, acryl-based polymers, imide-based polymers, aryl ether-based polymers, amide-based polymers, fluorine-based polymers, p-xylene-based polymers, vinyl alcohol-based polymers, or any blends thereof. However, if necessary, the first planarization layer 116 may include an inorganic material.

The pixel circuit layer PCL may further include the connection electrode CML, and the connection electrode CML may be disposed on the first planarization layer 116. In this case, the connection electrode CML be connected to the first drain electrode DE1 or the first source electrode SE1 through a contact hole defined in the first planarization layer 116. The connection electrode CML may include a material with good conductivity. The connection electrode CML may include a conductive material, including Mo, Al, Cu, or Ti, and may have a single-layer or multi-layer structure including the conductive materials described above. For example, the connection electrode CML may have a multi-layer structure of Ti/Al/Ti.

The second planarization layer 117 may cover the connection electrode CML. The second planarization layer 117 may have an approximately flat upper surface. The second planarization layer 117 may include an organic material. For example, the second planarization layer 117 may include general-purpose polymers, such as BCB, polyimide, HMDSO, PMMA, and PS, polymer derivatives having a phenol-based group, acryl-based polymers, imide-based polymers, aryl ether-based polymers, amide-based polymers, fluorine-based polymers, p-xylene-based polymers, vinyl alcohol-based polymers, or any blends thereof. In some embodiments, the second planarization layer 117 may include an inorganic material.

The display element layer DEL may be disposed on the pixel circuit layer PCL. The display element layer DEL may include a display element DPE and a pixel-defining film 119. The display element DPE may be electrically connected to the pixel circuit PC (see, e.g., FIG. 4). The display element DPE may be an organic light-emitting diode including, for example, a pixel electrode 210, an opposite electrode 230, and an emission layer 220 therebetween. The display element DPE being electrically connected to the pixel circuit PC may be understood as the pixel electrode 210 of the organic light-emitting diode being electrically connected to the pixel circuit PC.

For example, the pixel electrode 210 may be disposed on the second planarization layer 117 having a flat upper surface. The pixel electrode 210 may be electrically connected to the connection electrode CML through a contact hole defined in the second planarization layer 117. Because the connection electrode CML is connected to the first drain electrode DE1 or the first source electrode SE1 through a contact hole defined in the first planarization layer 116, the pixel electrode 210 may be electrically connected to the pixel circuit PC through the connection electrode CML.

The pixel electrode 210 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In some other embodiments, the pixel electrode 210 may include a reflective film including Ag, Mg, Al, Pt, Pd, Au, Ni, Nd, Ir, Cr, or any compounds thereof. In some other embodiments, the pixel electrode 210 may further include a film formed of ITO, IZO, ZnO, or In₂O₃, over/under the reflective film described above.

The pixel-defining film 119 may be disposed on the second planarization layer 117. The pixel-defining film 119 may cover an edge of the pixel electrode 210. For example, the pixel-defining film 119 may have an opening 119OP through which a central portion of the pixel electrode 210 is exposed, thereby defining an emission area of the pixel. For example, the opening 119OP defined in the pixel-defining film 119 may expose the central portion of the pixel electrode 210, and an emission area of light emitted by the display element DPE may be defined by the opening 119OP. In addition, the pixel-defining film 119 increases a distance between an edge of the pixel electrode 210 and the opposite electrode 230 over the pixel electrode 210, thereby preventing or substantially reducing the likelihood of an arc or the like from occurring at the edge of the pixel electrode 210. The pixel-defining film 119 may include an organic insulating material, such as polyimide, polyamide, acryl-based resin, BCB, HMDSO, or phenolic resin, and the pixel-defining film 119 may be formed by spin coating or the like. In some embodiments, the pixel-defining film 119 may include a light-blocking material.

The emission layer 220 may be disposed on the pixel electrode 210. For example, the emission layer 220 may be disposed in the opening 119OP defined in the pixel-defining film 119 and may overlap with the pixel electrode 210. The emission layer 220 may include a low-molecular weight material or a polymer material, and may emit red, green, or blue light. However, one or more embodiments are not limited thereto. For example the emission layer 220 may emit white light or light of a different color, and any organic light-emitting material that can emit light may be used for the emission layer 220 without limitation.

Accordingly, the display element DPE may emit red, green, or blue light. For example, because the display element DPE may be provided in plurality as described above, some of the plurality of display elements DPE may emit red light, and some other ones of the plurality of display elements DPE may emit green light, and some other ones of the plurality of display elements DPE may emit blue light. The display element DPE capable of emitting red light may have the emission layer 220 capable of emitting red light, the display element DPE capable of emitting green light may have the emission layer 220 capable of emitting green light, and the display element DPE capable of emitting blue light may have the emission layer 220 capable of emitting blue light.

The opposite electrode 230 may be disposed on the emission layer 220. The opposite electrode 230 may be formed as a single body in the plurality of display elements DPE and may correspond to the plurality of pixel electrodes 210. The opposite electrode 230 may be formed to entirely cover the display area DA, and thus may also be disposed on the pixel-defining film 119. The opposite electrode 230 may have a conductive material with a low work function. For example, the opposite electrode 230 may include a transparent (e.g., semitransparent) layer including Ag, Mg, Al, Pt, Pd, Au, Ni, Nd, Ir, Cr, Li, Ca, or any alloys thereof. For example, the opposite electrode 230 may further include a layer, such as ITO, IZO, ZnO, or In₂O₃, on the (semi-) transparent layer including the materials described above.

The encapsulation layer 300 may be disposed on the display element layer DEL. For example, because the display element DPE of the display element layer DEL may be easily damaged by moisture or oxygen from the outside, the encapsulation layer 300 may cover and protect the display element DPE. As shown in FIG. 4, the encapsulation layer 300 may include a first inorganic encapsulation layer 310, an organic encapsulation layer 320, and a second inorganic encapsulation layer 330. For example, the encapsulation layer 300 including the first inorganic encapsulation layer 310, the second inorganic encapsulation layer 330, and the organic encapsulation layer 320 may be disposed on the opposite electrode 230, the organic encapsulation layer 320 being disposed between the first inorganic encapsulation layer 310 and the second inorganic encapsulation layer 330.

The first inorganic encapsulation layer 310 may cover the opposite electrode 230, and may include SiOₓ, SiNₓ, SiOₓN_{y}, and/or the like. In some embodiments, other layers, such as a capping layer, may be between the first inorganic encapsulation layer 310 and the opposite electrode 230. Because the first inorganic encapsulation layer 310 is formed along a structure thereunder, an upper surface of the first inorganic encapsulation layer 310 may not be flat as in FIG. 4. The organic encapsulation layer 320 may cover the first inorganic encapsulation layer 310 so that the upper surface of the first inorganic encapsulation layer 310 may be approximately flat, unlike in the case with first inorganic encapsulation layer 310. The organic encapsulation layer 320 may include one or more materials selected from the group consisting of polyethylene terephthalate, polyethylene naphthalate, polycarbonate, polyimide, polyethylene sulfonate, polyoxymethylene, polyarylate, and HMDSO. The second inorganic encapsulation layer 330 may cover the organic encapsulation layer 320, and may include SiOₓ, SiNₓ, SiOₓN_{y}, and/or the like.

Because the encapsulation layer 300 includes the first inorganic encapsulation layer 310, the organic encapsulation layer 320, and the second inorganic encapsulation layer 330, even when cracks occur in the encapsulation layer 300 through this multi-layer structure, the cracks may be prevented from connecting between the first inorganic encapsulation layer 310 (or the likelihood of this occurring may be substantially reduced) and the organic encapsulation layer 320 or between the organic encapsulation layer 320 and the second inorganic encapsulation layer 330. Through this, the formation of a passage through which moisture or oxygen from the outside permeates into the display apparatus 1 may be prevented or reduced.

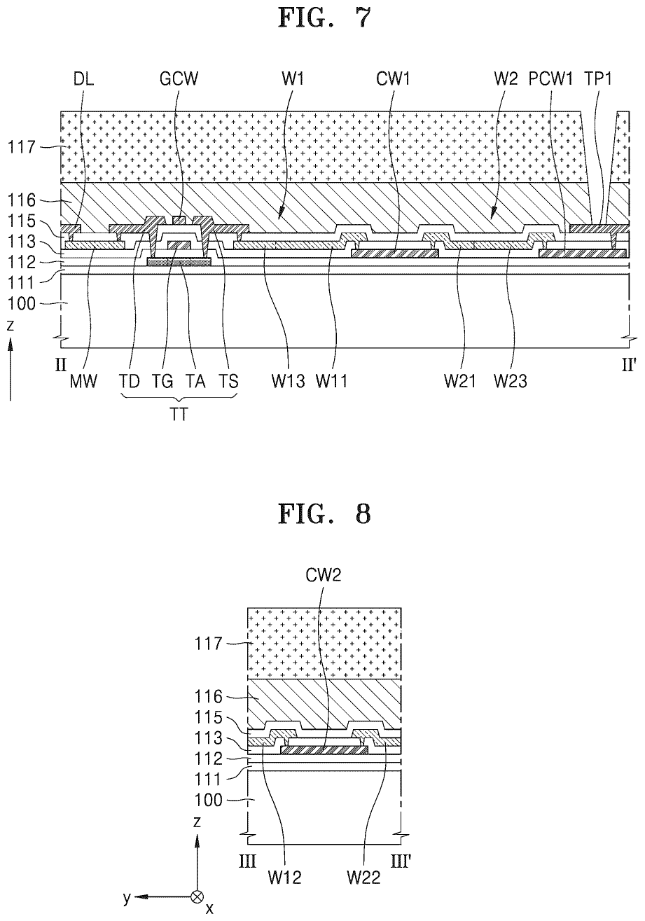

FIG. 6 is an enlarged view schematically illustrating region A of the display apparatus 1 of FIG. 3 according to some embodiments of the present disclosure. FIG. 7 is a cross-sectional view taken along the line II-II′ and schematically illustrating a cross section of the display apparatus 1 of FIG. 6 according to some embodiments of the present disclosure. FIG. 8 is a cross-sectional view taken along the line III-III′ and schematically illustrating a cross section of the display apparatus 1 of FIG. 6 according to some embodiments of the present disclosure.

As shown in FIG. 6, the display apparatus 1 may include the lighting inspection unit LT and a first test pad TP1 on the non-display area NDA, for example, the second area A2. The lighting inspection unit LT may include a plurality of test transistors TT and a first line W1. In addition, the display apparatus 1 may further include a second line W2, a first connection line CW1, and a second connection line CW2.

The plurality of test transistors TT of the lighting inspection unit LT may be transistors for lighting inspection to identify whether the pixels in the display area DA operate normally in a manufacturing process for the display apparatus 1. Similar to the first transistor T1 described above, each of the plurality of test transistors TT included in the lighting inspection unit LT may include a test semiconductor layer TA, a test gate electrode TG, a test source electrode TS, and a test drain electrode TD.

For example, as shown in FIG. 7, the test semiconductor layer TA may be disposed on the buffer layer 111, and the test gate electrode TG may overlap with a channel region of the test semiconductor layer TA. In order to ensure insulation between the test semiconductor layer TA and the test gate electrode TG, the first gate insulating layer 112 may be between the test semiconductor layer TA and the test gate electrode TG. Further, the second gate insulating layer 113 may cover the test gate electrode TG. Each of the test drain electrode TD and the test source electrode TS may be disposed on the interlayer insulating layer 115. For example, the test semiconductor layer TA, the test gate electrode TG, the test source electrode TS, and the test drain electrode TD include materials and structures identical or similar to materials and structures included in the first semiconductor layer Act1, the first gate electrode GE1, the first drain electrode DE1, and the first source electrode SE1, and thus redundant descriptions thereof are omitted.

For convenience, FIG. 6 only shows a position relationship among the test semiconductor layer TA, the test gate electrode TG, the test source electrode TS, and the test drain electrode TD. Further, FIG. 6 also shows a position relationship between various other lines and pads.

The test gate electrode TG of the plurality of test transistors TT are electrically connected to each other via a bridge line, a gate connection line GCW. For example, the gate connection line GCW, which is disposed on a layer different from a layer on which the test gate electrodes TG are disposed, may electrically connect the test gate electrodes TG spaced apart from each other. In FIG. 7, the gate connection line GCW is in direct contact with the test gate electrodes TG defined in the second gate insulating layer 113 and the interlayer insulating layer 115, to electrically connect the test gate electrodes TG spaced apart from each other, the second gate insulating layer 113 and the interlayer insulating layer 115 being between the gate connection line GCW and the test gate electrodes TG. This may be applicable to embodiments and modifications thereof described below. Accordingly, at least a portion of the gate connection line GCW and the test gate electrodes TG may be positioned on an imaginary straight line (e.g., in a straight line extending in the x-axis direction), as shown in FIG. 6.

Because each of the test transistors TT includes the test source electrode TS and the test drain electrode TD, the gate connection line GCW may include a material identical to materials of the test source electrode TS and the test drain electrode TD, e.g., a conductive material, including Mo, Al, Cu, and Ti, and may have a single-layer or multi-layer structure including the conductive materials described above. Further, the gate connection line GCW may be disposed on a layer identical to a layer on which the test source electrode TS and the test drain electrode TD are disposed, i.e., on the interlayer insulating layer 115. Accordingly, the gate connection line GCW may be connected to the test gate electrodes TG thereunder through a contact hole defined in the second gate insulating layer 113 and the interlayer insulating layer 115.

As shown in FIG. 3, the plurality of data lines DL may extend to the second area A2 across the display area DA. For example, each of the plurality of data lines DL may extend in the second direction (e.g., the y-axis direction). Each of the plurality of test transistors TT may be electrically connected to a corresponding one of the plurality of data lines DL. When electrical signals are concurrently (e.g., simultaneously or substantially simultaneously) transmitted to the test gate electrodes TG electrically connected to each other of the plurality of test transistors TT, a channel may be simultaneously formed in the test semiconductor layers TA of the plurality of test transistors TT. When the plurality of test transistors TT are concurrently (e.g., simultaneously or substantially simultaneously) turned on as described above, electrical signals from the first test pad TP1 may be transmitted to the plurality of test transistors TT. Accordingly, pixels of the data lines DL electrically connected to the plurality of data lines DL emit light, so that the pixels in the data lines DL may be inspected for defects.

For example, when the display apparatus is used after the manufacturing of the display apparatus is completed, the test transistors TT may be turned off. For example, when the test transistors TT are p-type thin-film transistors, the test transistors TT may be turned off by applying a VGH bias voltage (positive bias voltage) to the first test pad TP1. Accordingly, a signal from a driving chip may be transmitted to the data line DL.

The plurality of data lines DL extending to the second area A2 across the display area DA may include a material identical to those of the test source electrode TS and the test drain electrode TD of the test transistor TT (e.g., a conductive material including Mo, Al, Cu, or Ti). Also, the plurality of data lines DL may have a single-layer or multi-layer structure including the conductive materials described above. Further, the plurality of data lines DL may be disposed on a layer identical to a layer on which the test source electrode TS and the test drain electrode TD are disposed. For example, the plurality of data lines DL may be disposed on the interlayer insulating layer 115. Each of the plurality of test transistors TT is electrically connected to a corresponding one of the plurality of data lines DL, and this may be possible by intermediate lines ML. For example, the intermediate lines ML may be connected to the plurality of data lines DL and the plurality of test transistors TT.

The intermediate lines ML may include a material identical to that of the second capacitor electrode CE2 (e.g., Al, Pt, Pd, Ag, Mg, Au, Ni, Nd, Ir, Cr, Ca, Mo, Ti, W, Cu, and/or the like), and may have a single-layer or multi-layer structure including the materials described above. Further, the intermediate lines ML may be disposed on a layer identical to a layer on which the second capacitor electrode CE2 is disposed. For example, the intermediate lines ML may be disposed on the second gate insulating layer 113. An end of the intermediate line ML in a direction to the data line DL may be connected to the data line DL thereon through a contact hole defined in the interlayer insulating layer 115, and an end of the intermediate line ML in a direction to the test transistor TT may be connected to the test drain electrode TD thereon through a contact hole defined in the interlayer insulating layer 115.

For example, the test source electrodes TS of the plurality of test transistors TT may be electrically connected to the first test pad TP1. This may be done by the first line W1, the second line W2, the first connection line CW1, and the second connection line CW2. For example, the first line W1 may extend in the first direction (e.g., the x-axis direction), and the second line W2 may be connected to the first line W1 through the first connection line CW1 and the second connection line CW2. The second line W2 may be connected to the first test pad TP1.

For example, the first line W1 may extend in the first direction (e.g., the x-axis direction). The second line W2 may extend in the first direction (e.g., the x-axis direction), similar to the first line W1, but may be spaced apart from the first line W1 in the second direction (e.g., the y-axis direction). The first line W1 and the second line W2 may include a material identical to that of the second capacitor electrode CE2 (e.g., Al, Pt, Pd, Ag, Mg, Au, Ni, Nd, Ir, Cr, Ca, Mo, Ti, W, Cu, and/or the like). The first line W1 and the second line W2 may have a single-layer or multi-layer structure including the materials described above. Further, the first line W1 and the second line W2 may be disposed on a layer identical to the layer on which the second capacitor electrode CE2 is disposed. For example, the first line W1 and the second line W2 may be disposed on the second gate insulating layer 113.

The first connection line CW1 may extend in the second direction (e.g., the y-axis direction). The second connection line CW2 may extend in the second direction (e.g., the y-axis direction), similar to the first connection line CW1, but may be spaced apart from the first connection line CW1 in the first direction (e.g., the x-axis direction). The first connection line CW1 and the second connection line CW2 may include a material identical to that of the test gate electrode TG (e.g., a conductive material including Mo, Al, Cu, or Ti). The first connection line CW1 and the second connection line CW2 may have a single-layer or multi-layer structure including the conductive materials described above. Further, the first connection line CW1 and the second connection line CW2 may be disposed on a layer identical to a layer on which the test gate electrode TG is disposed. For example, the first connection line CW1 and the second connection line CW2 may be disposed on the first gate insulating layer 112.

Accordingly, an end of the first connection line CW1 in a direction to the first line W1 may be connected to the first line W1 thereon through a contact hole defined in the second gate insulating layer 113, and an end of the first connection line CW1 in a direction to the second line W2 may be connected to the second line W2 thereon through a contact hole defined in the second gate insulating layer 113. Similarly, an end of the second connection line CW2 in a direction to the first line W1 may be connected to the first line W1 thereon through a contact hole defined in the second gate insulating layer 113, and an end of the second connection line CW2 in a direction to the second line W2 may be connected to the second line W2 thereon through a contact hole defined in the second gate insulating layer 113.

For example, the first line W1 may include a first-1 portion W11, a first-2 portion W12, and a first-3 portion W13. The first-1 portion W11 may be connected to the first connection line CW1, and the first-2 portion W12 may be connected to the second connection line CW2. As shown in FIG. 7, the first-1 portion W11 of the first line W1 may be in direct contact with the first connection line CW1 through a contact hole defined in the second gate insulating layer 113 disposed between the first line W1 and the first connection line CW1. Similarly, as shown in FIG. 8, the first-2 portion W12 of the first line W1 may be in direct contact with the second connection line CW2 through a contact hole defined in the second gate insulating layer 113 disposed between the first line W1 and the first connection line CW1.

In a plan view, the first-3 portion W13 may be positioned between the first-1 portion W11 and the first-2 portion W12. The test source electrodes TS of the plurality of test transistors TT may be connected to the first-3 portion W13. For example, as shown in FIG. 7, the test source electrode TS may be in direct contact with the first-3 portion W13 of the first line W1 through a contact hole defined in the interlayer insulating layer 115 disposed between the test source electrode TS and the first line W1.

The second line W2 may include a second-1 portion W21, a second-2 portion W22, and a second-3 portion W23. The second-1 portion W21 may be connected to the first connection line CW1, and the second-2 portion W22 may be connected to the second connection line CW2. As shown in FIG. 7, the second-1 portion W21 of the second line W2 may be in direct contact with the first connection line CW1 through a contact hole defined in the second gate insulating layer 113 disposed between the second line W2 and the first connection line CW1. Similarly, as shown in FIG. 8, the second-2 portion W22 of the second line W2 may be in direct contact with the second connection line CW2 through a contact hole defined in the second gate insulating layer 113 disposed between the second line W2 and the second connection line CW2.

In a plan view, the second-3 portion W23 may be positioned between the second-1 portion W21 and the second-2 portion W22. The first test pad TP1 may be connected to the second-3 portion W23 described above. For example, the first test pad TP1 may be connected to the second-3 portion W23 through a first pad connection line PCW1. For example, the first test pad TP1 may be connected to the second line W2.

For example, as shown in FIG. 7, an end of the first pad connection line PCW1 in the direction to the second line W2 may be connected to the second line W2 thereon through a contact hole defined in the second gate insulating layer 113, and an end of the first pad connection line PCW1 in the direction to the first test pad TP1 may be connected to the first test pad TP1 thereon through a contact hole defined in the second gate insulating layer 113. Accordingly, the first test pad TP1 may be electrically connected to the plurality of test transistors TT.

The first test pad TP1 may include a material identical to that of the test source electrode TS and the test drain electrode TD of the test transistor TT (e.g., a conductive material including Mo, Al, Cu, or Ti). Also, the first test pad TP1 may have a single-layer or multi-layer structure including the conductive materials described above. Further, the first test pad TP1 may be disposed on a layer identical to the layer on which the test source electrode TS and the test drain electrode TD are disposed. For example, the first test pad TP1 may be disposed on the interlayer insulating layer 115.

In some embodiments, the first test pad TP1 may be connected to a central portion of the second line W2 (e.g., a central portion of the second-3 portion W23). For example, a length between the second-1 portion W21 and a portion of the second-3 portion W23 connected to the first test pad TP1 may be equal or similar to a length between the second-2 portion W22 and the portion of the second-3 portion W23 connected to the first test pad TP1.

For example, an upper surface of the first test pad TP1 may be exposed to the outside through an opening defined in the first planarization layer 116 and the second planarization layer 117, and accordingly, an electrical signal may be transmitted to the first test pad TP1. As described above, each of the plurality of test transistors TT may be electrically connected to a corresponding one of the plurality of data lines DL, and the plurality of data lines DL may extend to the second area A2 across the display area DA. Because each of the plurality of data lines DL is electrically connected to some of the plurality of display elements DPE, an electrical signal may be transmitted to the first test pad TP1 so that a lighting inspection of the data lines DL may be performed.

For example, a test pad electrically connected to the lighting inspection unit LT may be disposed on the second-2 area A22 of the second area A2 (see, e.g., FIG. 1). For example, the first test pad TP1 may be disposed on the second-2 area A22. Because a size (or an area) of the second-2 area A22 is greater than a size (or an area) of the second-1 area A21 (see, e.g., FIG. 1), the first test pad TP1 may be disposed on the second-2 area A22 to more efficiently utilize a space of the display apparatus 1. For example, because the second-1 area A21 may not have a sufficient area to dispose the test pad electrically connected to the lighting inspection unit LT, the test pad electrically connected to the lighting inspection unit LT may not be disposed on the second-1 area A21 and may be disposed on the second-2 area A22.

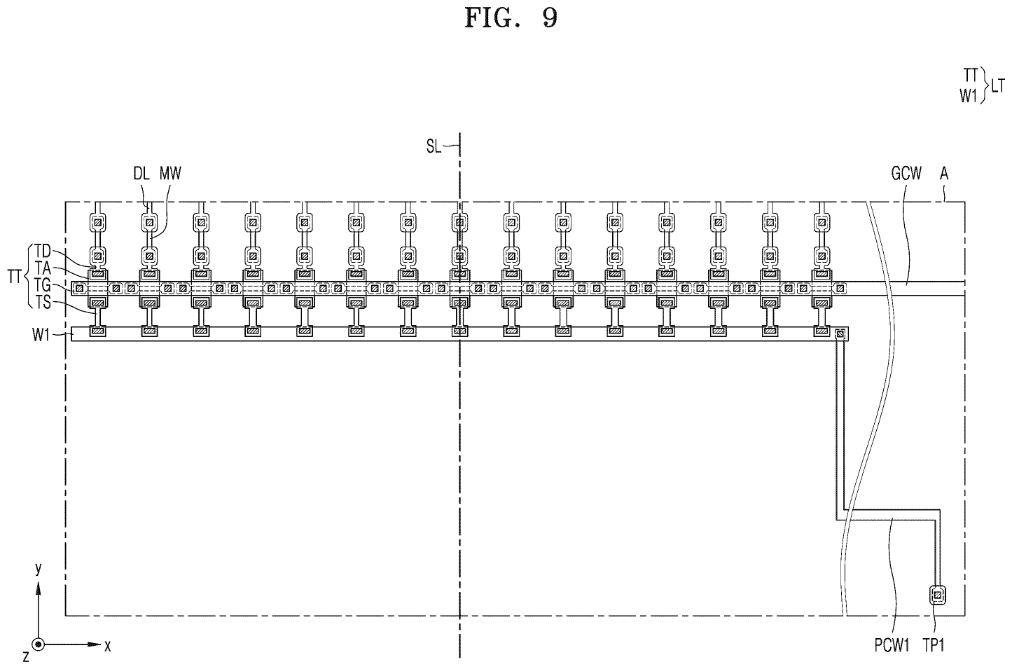

FIG. 9 is a plan view schematically illustrating a portion of a display apparatus according to a Comparative Example. For example, FIG. 9 corresponds to FIG. 6. In a case with the display apparatus according to the Comparative Example, a test pad electrically connected to the lighting inspection unit LT, i.e., the first test pad TP1, may only be disposed on the second-2 area A22, and the first test pad TP1 may only be connected to one end of the first line W1 in the direction to the first test pad TP1. For example, although not clearly shown in FIG. 9, the first test pad TP1 may only be connected to an end of the first line W1 in the direction to the first test pad TP1 considering positions of elements of the display apparatus 1 other than the lighting inspection unit LT and the first test pad TP1.

For example, an electrical signal transmitted to the test transistor TT positioned close to a portion of the first line W1 connected to the first test pad TP1 may be different from an electrical signal transmitted to the test transistor TT positioned far away from the portion of the first line W1 connected to the first test pad TP1. For example, a delay in the transmission of electrical signals to the test transistors TT may occur. Accordingly, the lighting test result of the display apparatus 1 may be inaccurate.

However, in a case of the display apparatus 1 according to the present disclosure, the first test pad TP1 may be connected to the second line W2, and the second line W2 may be connected to the first line W1 through the first connection line CW1 and the second connection line CW2. For example, in the case of the display apparatus 1 according to the present disclosure, an end of the first line W1 in the opposite direction of the first test pad TP1 as well as the end of the first line W1 in the direction to the first test pad TP1 may be connected to the first test pad TP1. In this case, a difference between electrical signals transmitted to the test transistors TT may be reduced. Accordingly, the lighting test result of the display apparatus 1 may be more accurate. For example, display apparatus 1 may be accurately inspected for defects.

For example, in FIG. 6, all of the plurality of test transistors TT of the lighting inspection unit LT are connected to the first line W1. However, one or more embodiments are not limited thereto. For example, only some of the plurality of test transistors TT of the lighting inspection unit LT may be connected to the first line W1.

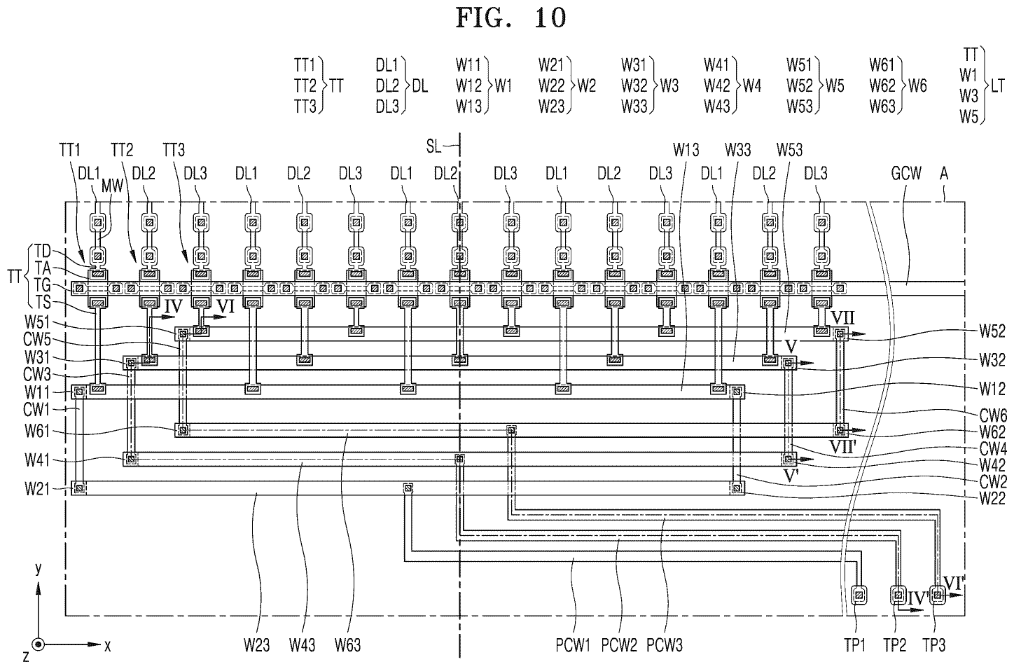

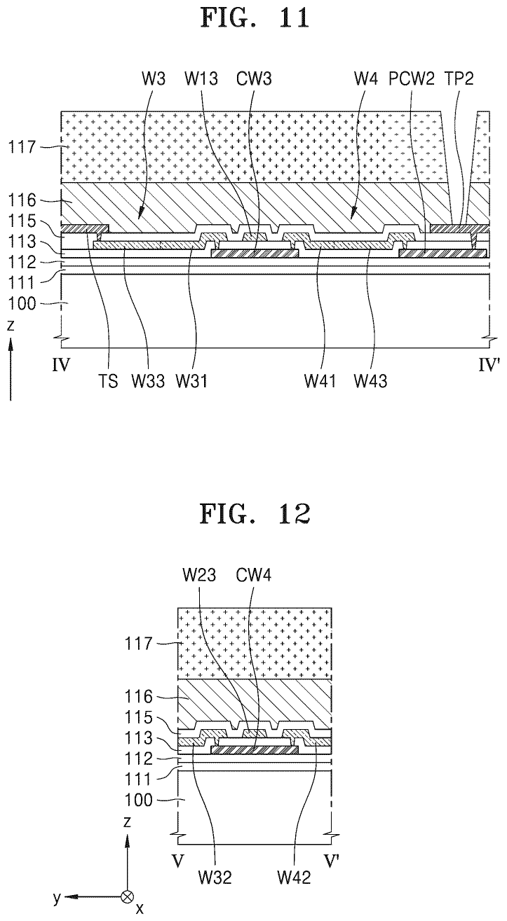

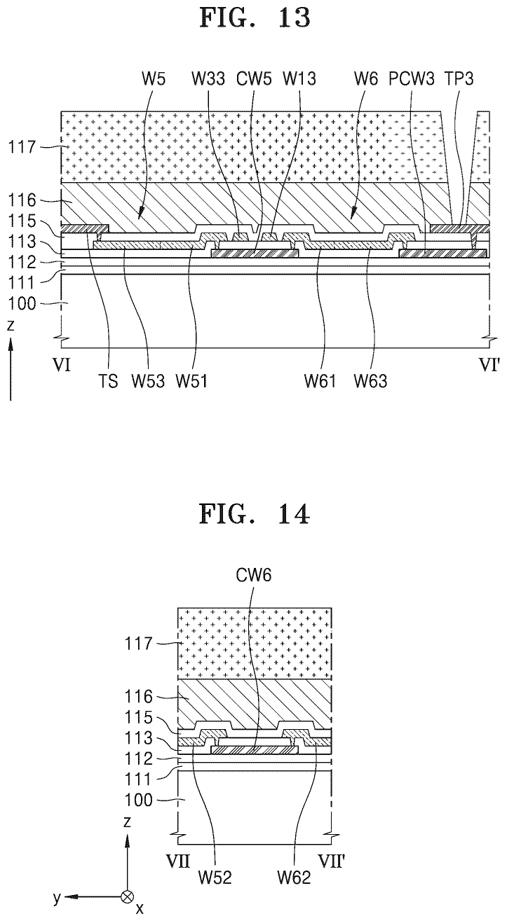

FIG. 10 is a plan view schematically illustrating a portion of the display apparatus 1 according to some other embodiments of the present disclosure. FIG. 11 is a cross-sectional view taken along the line IV-IV′ and schematically illustrating a cross section of the display apparatus 1 of FIG. 10 according to some embodiments of the present disclosure. FIG. 12 is a cross-sectional view taken along the line V-V′ and schematically illustrating a cross section of the display apparatus 1 of FIG. 10 according to some embodiments of the present disclosure. FIG. 13 is a cross-sectional view taken along the line VI-VI′ and schematically illustrating a cross section of the display apparatus 1 of FIG. 10 according to some embodiments of the present disclosure. FIG. 14 is a cross-sectional view taken along the line VII-VII′ and schematically illustrating a cross section of the display apparatus 1 of FIG. 10 according to some embodiments of the present disclosure. For example, FIG. 10 corresponds to FIG. 6. The display apparatus 1 according to the present embodiment is similar to the display apparatus 1 described above with reference to FIGS. 1 to 8, and thus, differences from the display apparatus 1 described above are mainly described below with reference to FIGS. 1 to 8. In FIGS. 10 to 14, the same reference characters as those of FIGS. 1 to 8 denote the same member, and redundant descriptions thereof are omitted.

In the case of the display apparatus 1 described above with reference to FIGS. 1 to 8, the plurality of data lines DL may extend to the second area A2 across the display area DA, and each of the plurality of test transistors TT of the lighting inspection unit LT may be electrically connected to the corresponding one of the plurality of data lines DL. Also in the case of the display apparatus 1 according to the some embodiments, the plurality of data lines DL may extend to the second area A2 across the display area DA, and each of the plurality of test transistors TT of the lighting inspection unit LT may be electrically connected to the corresponding one of the plurality of data lines DL.

However, as shown in FIG. 10, in the display apparatus 1 according to some embodiments, only some of the plurality of test transistors TT of the lighting inspection unit LT may be connected to the first line W1. The display apparatus 1 according to some embodiments may further include a third line W3 and a fifth line W5, wherein the third line W3 is connected to some other ones of the plurality of test transistors TT, and the fifth line W5 is connected to some other ones of the plurality of test transistors TT.

For example, the plurality of test transistors TT may include a plurality of first test transistors TT1, a plurality of second test transistors TT2, and a plurality of third test transistors TT3. The plurality of data lines DL may include a plurality of first data lines DL1, a plurality of second data lines DL2, and a plurality of third data lines DL3.

Each of the plurality of first test transistors TT1 may be electrically connected to a corresponding one of the plurality of first data lines DL1, and the plurality of first test transistors TT1 may be connected to the first line W1. Each of the plurality of second test transistors TT2 may be electrically connected to a corresponding one of the plurality of second data lines DL2, and the plurality of second test transistors TT2 may be connected to the third line W3. Each of the plurality of third test transistors TT3 may be electrically connected to a corresponding one of the plurality of third data lines DL3, and the plurality of third test transistors TT3 may be connected to the fifth line W5.

As described above, the display element DPE may emit red, green, or blue light. The display element DPE may be provided in plurality. For example, the plurality of display elements DPE may include a plurality of first display elements capable of emitting first-color light, a plurality of second display elements capable of emitting second-color light, and a plurality of third display elements capable of emitting third-color light, wherein the second-color light is different from the first-color light, and the third-color light is different from the first-color light and the second-color light. The first-color light may be red light (e.g., light in a wavelength band of about 580 nm to about 780 nm). The second-color light may be green light (e.g., light in a wavelength band of about 495 nm to about 580 nm), and the third-color-light may be blue light (e.g., light in a wavelength band of about 400 nm to about 495 nm).

The plurality of first data lines DL1 may be electrically connected to the display elements DPE capable of emitting the first-color light from among the plurality of display elements DPE. For example, each of the plurality of first data lines DL1 may be electrically connected to at least one of a plurality of first display elements. The plurality of second data lines DL2 may be electrically connected to the display elements DPE capable of emitting the second-color light from among the plurality of display elements DPE, and the plurality of third data lines DL3 may be electrically connected to the display elements DPE capable of emitting the third-color light from among the plurality of display elements DPE. For example, each of the second data lines DL2 may be electrically connected to at least one of the plurality of second display elements, and each of the third data lines DL3 may be electrically connected to at least one of the plurality of third display elements.

In this case, the display apparatus 1 according to the present embodiment may further include a fourth line W4, a third connection line CW3, a fourth connection line CW4, a sixth line W6, a fifth connection line CW5, and a sixth connection line CW6. However, the display apparatus 1 according to some embodiments may further include a second test pad TP2 and a third test pad TP3 in the non-display area NDA (e.g., the second area A2).

For example, the third line W3 may extend in the first direction (e.g., the x-axis direction), and the fourth line W4 may be connected to the third line W3 through the third connection line CW3 and the fourth connection line CW4. The fourth line W4 may be connected to the second test pad TP2. The fifth line W5 may extend in the first direction (e.g., the x-axis direction), and the sixth line W6 may be connected to the fifth line W5 through the fifth connection line CW5 and the sixth connection line CW6. The sixth line W6 may be connected to the third test pad TP3.

For example, the third line W3 may extend in the first direction (e.g., the x-axis direction). The fourth line W4 may extend in the first direction (e.g., the x-axis direction), similar to the third line W3, but may be spaced apart from the third line W3 in the second direction (e.g., the y-axis direction). The third connection line CW3 may extend in the second direction (e.g., the y-axis direction). The fourth connection line CW4 may extend in the second direction (e.g., the y-axis direction), similar to the third connection line CW3, but may be spaced apart from the third connection line CW3 in the first direction (e.g., the x-axis direction).

For example, the third line W3, the fourth line W4, the third connection line CW3, and the fourth connection line CW4 may include materials and structures identical or similar to those of the first line W1, the second line W2, the first connection line CW1, and the second connection line CW2, respectively. Thus, redundant descriptions thereof are omitted. The third line W3, the fourth line W4, the third connection line CW3, and the fourth connection line CW4 are respectively disposed on layers identical or similar to those on which the first line W1, the second line W2, the first connection line CW1, and the second connection line CW2 are respectively disposed. Thus, redundant descriptions thereof are omitted.

Accordingly, an end of the third connection line CW3 in a direction to the third line W3 may be connected to the third line W3 thereon through a contact hole defined in the second gate insulating layer 113, and an end of the third connection line CW3 in a direction to the fourth line W4 may be connected to the fourth line W4 thereon through a contact hole defined in the second gate insulating layer 113. Similarly, an end of the fourth connection line CW4 in the direction to the third line W3 may be connected to the third line W3 thereon through a contact hole defined in the second gate insulating layer 113, and an end of the fourth connection line CW4 in the direction to the fourth line W4 may be connected to the fourth line W4 thereon through a contact hole defined in the second gate insulating layer 113.

For example, the third line W3 may include a third-1 portion W31, a third-2 portion W32, and a third-3 portion W33. The third-1 portion W31 may be connected to the third connection line CW3, and the third-2 portion W32 may be connected to the fourth connection line CW4. As shown in FIG. 11, the third-1 portion W31 of the third line W3 may be in direct contact with the third connection line CW3 through a contact hole defined in the second gate insulating layer 113 disposed between the third line W3 and the third connection line CW3. Similarly, as shown in FIG. 12, the third-2 portion W32 of the third line W3 may be in direct contact with the fourth connection line CW4 through a contact hole defined in the second gate insulating layer 113 disposed between the third line W3 and the third connection line CW3.

In a plan view, the third-3 portion W33 may be positioned between the third-1 portion W31 and the third-2 portion W32. The test source electrodes TS of the plurality of test transistors TT may be connected to the third-3 portion W33. For example, as shown in FIG. 11, the test source electrode TS may be in direct contact with the third-3 portion W33 of the third line W3 through a contact hole defined in the interlayer insulating layer 115 disposed between the test source electrode TS and the third line W3.

The fourth line W4 may include a fourth-1 portion W41, a fourth-2 portion W42, and a fourth-3 portion W43. The fourth-1 portion W41 may be connected to the third connection line CW3, and the fourth-2 portion W42 may be connected to the fourth connection line CW4. As shown in FIG. 11, the fourth-1 portion W41 of the fourth line W4 may be in direct contact with the third connection line CW3 through a contact hole defined in the second gate insulating layer 113 disposed between the fourth line W4 and the third connection line CW3. Similarly, as shown in FIG. 12, the fourth-2 portion W42 of the fourth line W4 may be in direct contact with the fourth connection line CW4 through a contact hole defined in the second gate insulating layer 113 disposed between the fourth line W4 and the fourth connection line CW4.

In a plan view, the fourth-3 portion W43 may be positioned between the fourth-1 portion W41 and the fourth-2 portion W42. The second test pad TP2 may be connected to the fourth-3 portion W43 described above. For example, the second test pad TP2 may be connected to the fourth-3 portion W43 through a second pad connection line PCW2. For example, the second test pad TP2 may be connected to the fourth line W4.

For example, as shown in FIG. 11, an end of the second pad connection line PCW2 in the direction to the fourth line W4 may be connected to the fourth line W4 thereon through a contact hole defined in the second gate insulating layer 113, and an end of the second pad connection line PCW2 in the direction to the second test pad TP2 may be connected to the second test pad TP2 thereon through a contact hole defined in the second gate insulating layer 113. Accordingly, the second test pad TP2 may be electrically connected to some of the plurality of test transistors TT.

The fifth line W5 may extend in the first direction (e.g., the x-axis direction), and the sixth line W6 may be connected to the fifth line W5 through the fifth connection line CW5 and the sixth connection line CW6. The sixth line W6 may be connected to the third test pad TP3. The fifth line W5 may extend in the first direction (e.g., the x-axis direction), and the sixth line W6 may be connected to the fifth line W5 through the fifth connection line CW5 and the sixth connection line CW6. The sixth line W6 may be connected to the third test pad TP3.

For example, the fifth line W5 may extend in the first direction (e.g., the x-axis direction). The sixth line W6 may extend in the first direction (e.g., the x-axis direction), similar to the fifth line W5, but may be spaced apart from the fifth line W5 in the second direction (e.g., the y-axis direction). The fifth connection line CW5 may extend in the second direction (e.g., the y-axis direction). The sixth connection line CW6 may extend in the second direction (e.g., the y-axis direction), similar to the fifth connection line CW5, but may be spaced apart from the fifth connection line CW5 in the first direction (e.g., the x-axis direction).

For example, the fifth line W5, the sixth line W6, the fifth connection line CW5, and the sixth connection line CW6 include materials and structures identical or similar to those of the first line W1, the second line W2, the first connection line CW1, and the second connection line CW2, respectively. Thus, redundant descriptions thereof are omitted. The fifth line W5, the sixth line W6, the fifth connection line CW5, and the sixth connection line CW6 are respectively disposed on layers identical or similar to those on which the first line W1, the second line W2, the first connection line CW1, and the second connection line CW2 are respectively disposed. Thus, redundant descriptions thereof are omitted.

Accordingly, an end of the fifth connection line CW5 in a direction to the fifth line W5 may be connected to the fifth line W5 thereon through a contact hole defined in the second gate insulating layer 113, and an end of the fifth connection line CW5 in a direction to the sixth line W6 may be connected to the sixth line W6 thereon through a contact hole defined in the second gate insulating layer 113. Similarly, an end of the sixth connection line CW6 in the direction to the fifth line W5 may be connected to the fifth line W5 thereon through a contact hole defined in the second gate insulating layer 113, and an end of the sixth connection line CW6 in the direction to the sixth line W6 may be connected to the sixth line W6 thereon through a contact hole defined in the second gate insulating layer 113.

For example, the fifth line W5 may include a fifth-1 portion W51, a fifth-2 portion W52, and a fifth-3 portion W53. The fifth-1 portion W51 may be connected to the fifth connection line CW5, and the fifth-2 portion W52 may be connected to the sixth connection line CW6. As shown in FIG. 13, the fifth-1 portion W51 of the fifth line W5 may be in direct contact with the fifth connection line CW5 through a contact hole defined in the second gate insulating layer 113 disposed between the fifth line W5 and the fifth connection line CW5. Similarly, as shown in FIG. 14, the fifth-2 portion W52 of the fifth line W5 may be in direct contact with the sixth connection line CW6 through a contact hole defined in the second gate insulating layer 113 disposed between the fifth line W5 and the fifth connection line CW5.

In a plan view, the fifth-3 portion W53 may be positioned between the fifth-1 portion W51 and the fifth-2 portion W52. The test source electrodes TS of the plurality of test transistors TT may be connected to the fifth-3 portion W53. For example, as shown in FIG. 13, the test source electrode TS may be in direct contact with the fifth-3 portion W53 of the fifth line W5 through a contact hole defined in the interlayer insulating layer 115 disposed between the test source electrode TS and the fifth line W5.

The sixth line W6 may include a sixth-1 portion W61, a sixth-2 portion W62, and a sixth-3 portion W63. The sixth-1 portion W61 may be connected to the fifth connection line CW5, and the sixth-2 portion W62 may be connected to the sixth connection line CW6. As shown in FIG. 13, the sixth-1 portion W61 of the sixth line W6 may be in direct contact with the fifth connection line CW5 through a contact hole defined in the second gate insulating layer 113 disposed between the sixth line W6 and the fifth connection line CW5. Similarly, as shown in FIG. 14, the sixth-2 portion W62 of the sixth line W6 may be in direct contact with the sixth connection line CW6 through a contact hole defined in the second gate insulating layer 113 disposed between the sixth line W6 and the sixth connection line CW6.

In a plan view, the sixth-3 portion W63 may be positioned between the sixth-1 portion W61 and the sixth-2 portion W62. The third test pad TP3 may be connected to the sixth-3 portion W63 described above. For example, the third test pad TP3 may be connected to the sixth-3 portion W63 through a third pad connection line PCW3. For example, the third test pad TP3 may be connected to the sixth line W6.

For example, as shown in FIG. 13, an end of the third pad connection line PCW3 in the direction to the sixth line W6 may be connected to the sixth line W6 thereon through a contact hole defined in the second gate insulating layer 113, and an end of the third pad connection line PCW3 in the direction to the third test pad TP3 may be connected to the third test pad TP3 thereon through a contact hole defined in the second gate insulating layer 113. Accordingly, the third test pad TP3 may be electrically connected to some of the plurality of test transistors TT.

In some embodiments, the second test pad TP2 may be connected to a central portion of the fourth line W4 (e.g., a central portion of the fourth-3 portion W43). For example, a length between the fourth-1 portion W41 and a portion of the fourth-3 portion W43 connected to the second test pad TP2 may be equal or similar to a length between the fourth-2 portion W42 and the portion of the fourth-3 portion W43 connected to the second test pad TP2. Similarly, the third test pad TP3 may be connected to a central portion of the sixth line W6 e.g., (a central portion of the sixth-3 portion W63). In other words, a length between the sixth-1 portion W61 and a portion of the sixth-3 portion W63 connected to the third test pad TP3 may be equal or similar to a length between the sixth-2 portion W62 and the portion of the sixth-3 portion W63 connected to the third test pad TP3.

For example, the second test pad TP2 and the third test pad TP3 electrically connected to the lighting inspection unit LT may be disposed on the second-2 area A22, similar to the first test pad TP1. Accordingly, the space of the display apparatus 1 may be utilized more efficiently.

Also, in a case of the display apparatus 1 according to some embodiments, the first test pad TP1 may be connected to the second line W2, and the second line W2 may be connected to the first line W1 through the first connection line CW1 and the second connection line CW2. Furthermore, the second test pad TP2 may be connected to the fourth line W4, and the fourth line W4 may be connected to the third line W3 through the third connection line CW3 and the fourth connection line CW4. The third test pad TP3 may be connected to the sixth line W6, and the sixth line W6 may be connected to the fifth line W5 through the fifth connection line CW5 and the sixth connection line CW6.

In other words, in the case of the display apparatus 1 according to some embodiments, an end of the first line W1 in the opposite direction of the first test pad TP1 as well as the end of the first line W1 in the direction to the first test pad TP1 may be connected to the first test pad TP1. Furthermore, an end of the second line W2 in the opposite direction of the second test pad TP2 as well as an end of the second line W2 in the direction to the second test pad TP2 may be connected to the second test pad TP2. An end of the third line W3 in the opposite direction of the third test pad TP3 as well as an end of the third line W3 in the direction to the third test pad TP3 may be connected to the third test pad TP3. In this case, a difference between electrical signals transmitted to the test transistors TT may be reduced. Accordingly, the lighting test result of the display apparatus 1 may be more accurate. In other words, the display apparatus 1 may be accurately inspected for defects during a manufacturing process.

According to some embodiments configured as described above, a display apparatus that may be accurately inspected for defects during a manufacturing process may be implemented. However, the scope of the disclosure is not limited by this effect.

In some embodiments, the display apparatus 1 may be included in an electronic device. The electronic device may further include an input module, a memory or storage, and a processor. The input module may be configured to receive input data from a user. The memory may be configured to store the input data. The processor may be configured to store the input data. The processor may be configured to perform computations based on the input data and provide output data. In some embodiments, the electronic device may be a smartphone. It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display apparatus comprising:
a substrate comprising a first area, a second area, and a bending area between the first area and the second area;
a plurality of test transistors on the second area;
a first line extending in a first direction;
a second line connected to the first line through a first connection line and a second connection line; and
a test pad connected to the second line,
wherein the first line comprises a first-1 portion connected to the first connection line, a first-2 portion connected to the second connection line, and a first-3 portion between the first-1 portion and the first-2 portion, and
wherein the plurality of test transistors are connected to the first-3 portion.

2. The display apparatus of claim 1, wherein the second line is spaced apart from the first line in a second direction crossing the first direction, and
wherein each of the first connection line and the second connection line extends in the second direction.

3. The display apparatus of claim 2, wherein the second line comprises a second-1 portion connected to the first connection line, a second-2 portion connected to the second connection line, and a second-3 portion between the second-1 portion and the second-2 portion, and
wherein the test pad is connected to the second-3 portion.

4. The display apparatus of claim 3, wherein the first area is symmetrical with respect to a symmetry line extending in the second direction, and
wherein the second area is asymmetrical with respect to the symmetry line.

5. The display apparatus of claim 4, wherein:
the second area comprises a second-1 area and a second-2 area;
in a plan view, the second-1 area is positioned on one side of the symmetry line;
in a plan view, the second-2 area is positioned on another side of the symmetry line;
a size of the second-2 area is greater than a size of the second-1 area; and
the test pad is on the second-2 area.

6. The display apparatus of claim 2, wherein the first area comprises a display area and a plurality of display elements on the display area, and
wherein each of the plurality of test transistors is electrically connected to a corresponding one of a plurality of data lines electrically connected to the plurality of display elements.

7. A display apparatus comprising:
a substrate comprising a first area, a second area, and a bending area between the first area and the second area;
a plurality of first test transistors, a plurality of second test transistors, and a plurality of third test transistors on the second area;
a first line extending in a first direction;
a second line connected to the first line through a first connection line and a second connection line; and
a first test pad connected to the second line,
wherein the first line comprises a first-1 portion connected to the first connection line, a first-2 portion connected to the second connection line, and a first-3 portion between the first-1 portion and the first-2 portion, and
wherein the plurality of first test transistors are connected to the first-3 portion.

8. The display apparatus of claim 7, wherein the second line is spaced apart from the first line in a second direction crossing the first direction, and
wherein each of the first connection line and the second connection line extends in the second direction.

9. The display apparatus of claim 8, wherein the second line comprises a second-1 portion connected to the first connection line, a second-2 portion connected to the second connection line, and a second-3 portion between the second-1 portion and the second-2 portion, and
wherein the first test pad is connected to the second-3 portion.

10. The display apparatus of claim 7, further comprising:
a third line extending in the first direction;
a fourth line connected to the third line through a third connection line and a fourth connection line; and
a second test pad connected to the fourth line,
wherein the third line comprises a third-1 portion connected to the third connection line, a third-2 portion connected to the fourth connection line, and a third-3 portion between the third-1 portion and the third-2 portion, and
wherein the plurality of second test transistors are connected to the third-3 portion.

11. The display apparatus of claim 10, wherein the fourth line is spaced apart from the third line in a second direction crossing the first direction,
wherein the fourth line extends in the first direction, and
wherein each of the third connection line and the fourth connection line extends in the second direction.

12. The display apparatus of claim 10, wherein the fourth line comprises a fourth-1 portion connected to the third connection line, a fourth-2 portion connected to the fourth connection line, and a first-3 portion between the fourth-1 portion and the fourth-2 portion, and
wherein the second test pad is connected to the fourth-3 portion.

13. The display apparatus of claim 10, further comprising:
a fifth line extending in the first direction;
a sixth line connected to the fifth line through a fifth connection line and a sixth connection line; and
a third test pad connected to the sixth line,
wherein the fifth line comprises a fifth-1 portion connected to the fifth connection line, a fifth-2 portion connected to the sixth connection line, and a fifth-3 portion between the fifth-1 portion and the fifth-2 portion, and
wherein the plurality of third test transistors are connected to the fifth-3 portion.

14. The display apparatus of claim 13, wherein the sixth line is spaced apart from the fifth line in a second direction crossing the first direction,
wherein the sixth line extends in the first direction, and
wherein each of the fifth connection line and the sixth connection line extends in the second direction.

15. The display apparatus of claim 13, wherein the sixth line comprises a sixth-1 portion connected to the fifth connection line, a sixth-2 portion connected to the sixth connection line, and a sixth-3 portion between the sixth-1 portion and the sixth-2 portion, and
wherein the third test pad is connected to the sixth-3 portion.

16. The display apparatus of claim 7, wherein the first area is symmetrical with respect to a symmetry line extending in a second direction crossing the first direction, and
wherein the second area is asymmetrical with respect to the symmetry line.

17. The display apparatus of claim 16, wherein:
the second area comprises a second-1 area and a second-2 area;
in a plan view, the second-1 area is positioned on one side of the symmetry line;
in a plan view, the second-2 area is positioned on another side of the symmetry line;
a size of the second-2 area is greater than a size of the second-1 area; and
the first test pad is on the second-2 area.

18. The display apparatus of claim 7, wherein:
the first area comprises a display area and a plurality of display elements on the display area;
each of the plurality of first test transistors is electrically connected to a corresponding one of a plurality of first data lines, the plurality of first data lines being electrically connected to display elements capable of emitting first-color light from among the plurality of display elements;
each of the plurality of second test transistors is electrically connected to a corresponding one of a plurality of second data lines, the plurality of second data lines being electrically connected to display elements capable of emitting second-color light from among the plurality of display elements; and
each of the plurality of third test transistors is electrically connected to a corresponding one of a plurality of third data lines, the plurality of third data lines being electrically connected to display elements capable of emitting third-color light from among the plurality of display elements.

19. An electronic device comprising:
an input module configured to receive input data from a user;
a memory configured to store the input data;
a processor configured to perform computations based on the input data and provide output data; and
a display apparatus configured to display an image to the user based, in part, on the input data and the output data, the display apparatus comprising:
a substrate comprising a first area, a second area, and a bending area between the first area and the second area;
a plurality of test transistors on the second area;
a first line extending in a first direction;
a second line connected to the first line through a first connection line and a second connection line; and
a test pad connected to the second line,
wherein the first line comprises a first-1 portion connected to the first connection line, a first-2 portion connected to the second connection line, and a first-3 portion between the first-1 portion and the first-2 portion, and
wherein the plurality of test transistors are connected to the first-3 portion.

20. The electronic device of claim 19, wherein the electronic device is a smartphone.
